(19) United States
(12) Patent Application Publication
(10) Pub. No.: US 2019/0146025 A1
(43) Pub. Date: May 16, 2019

(54) IMPROVEMENTS IN OR RELATING TO THE DETECTION OF A FAULT ON A POWER CONVERTER

(71) Applicant: General Electric Technology GmbH, Baden (CH)

(72) Inventors: Pablo BRIFF, Stafford (GB); Francisco Jose MORENO MUÑOZ, Navarra (ES); Kevin James DYKE, Stafford (GB)

(21) Appl. No.: 16/091,713

(22) PCT Filed: Apr. 3, 2017
(86) PCT No.: PCT/EP2017/057859

§ 371 Date: Oct. 5, 2018

(30) Foreign Application Priority Data
Apr. 5, 2016 (GB) 1605804.2

(51) Int. Cl. G01R 31/08; G01R 31/42; G01R 31/02; H02H 7/10

(52) U.S. Cl. CPC G01R 31/086; G01R 31/42; H02H 7/10; G01R 31/025; G01R 31/088

(57) ABSTRACT

A far-end power converter within a DC transmission network that includes a near-end power converter and at least one far-end power converter interconnected by portions of transmission medium. A method includes:
establishing a linear time-invariant model of the transmission medium;
determining a response characteristic of the time-invariant model;
measuring an output operating property of the transmission medium at the near-end power converter;
identifying one far-end power converter as being of interest;
deriving a corresponding input operating property of the transmission medium at the far-end power converter of interest by applying an inverse of the response characteristic of the time-invariant model to the measured output operating property of the transmission medium at the near-end power converter; and
comparing the derived input operating property with a fault characteristic to determine whether there is a fault on the far-end power converter of interest.

### FIELD OF THE DISCLOSURE

This disclosure relates to a method of detecting a fault on a far-end power converter within a DC transmission network, and to a DC transmission network including at least a near-end power converter that has a control unit programmed to determine whether there is a fault on an associated far-end power converter of interest.

### BACKGROUND

In DC transmission networks, such as high voltage direct current (HVDC) power transmission networks, alternating current (AC) power is typically converted to direct current (DC) power for transmission via one or more portions overhead lines and/or under-sea cables. This conversion removes the need to compensate for the AC capacitive load effects imposed by the transmission medium, i.e. the transmission line or cable, and reduces the cost per kilometre of the lines and/or cables, and thus becomes cost-effective when power needs to be transmitted over a long distance.

The conversion between DC power and AC power is utilized in power transmission networks where it is necessary to interconnect the DC and AC electrical networks. In any such power transmission network, power converters are required at each interface between AC and DC power to effect the required conversion; AC to DC or DC to AC.

Poor detection of a fault on such a power converter can potentially lead to damage in the converter hardware due to a rise in either current or voltage waveforms applied to the said hardware.

### SUMMARY

According to a first aspect of the disclosure there is provided a method of detecting a fault on a far-end power converter within a DC transmission network comprising a near-end power converter and at least one far-end power converter interconnected with one another by one or more portions of transmission medium, the method comprising the steps of:

(a) establishing a linear time-invariant model of the transmission medium lying between the or each far-end power converter and the near-end power converter;

(b) determining a response characteristic of the time-invariant model;

(c) measuring an output operating property of the transmission medium at the near-end power converter;

(d) identifying one far-end power converter as a far-end power converter of interest;

(e) deriving a corresponding input operating property of the transmission medium at the far-end power converter of interest by applying an inverse of the response characteristic of the time-invariant model to the measured output operating property of the transmission medium at the near-end power converter; and

(f) comparing the derived input operating property of the transmission medium at the far-end power converter of interest with a fault characteristic to determine whether there is a fault on the far-end power converter of interest.

Establishing a linear time-invariant model of the transmission medium lying between the or each far-end power converter and the near-end power converter, determining a response characteristic of the time-invariant model, and then using this to derive an input operating property of the transmission medium at the far-end power converter of interest (with it being possible to evaluate such an input operating property to establish whether there is a fault on the far-end power converter of interest) permits such fault detection to take place without the need for a dedicated communication link between the near-end power converter and the far-end power converter of interest.

The absence of a need for such a communication link is particularly desirable because a fault on a given far-end power converter, i.e. a fault in the transmission medium between the power converters, can impair or degrade an existing communication link to the point that it is unreliable during the occurrence of a fault.

Preferably step (f) of comparing the derived input operating property of the transmission medium at the far-end power converter of interest with a fault characteristic to determine whether there is a fault on the far-end power converter of interest includes predicting whether the derived input operating property will meet the fault characteristic and indicating that there is a fault on the far-end power converter of interest when the derived input operating property is predicted to meet the fault characteristic.

Optionally predicting whether the derived input operating property will meet the fault characteristic includes determining an expected output operating property at least one step ahead.

Such features of the method assist in detecting occurrence of a fault on the far-end power converter of interest more quickly.

In addition the foregoing features are useful in cancelling out known delays such as measurement, processing, and data conversion delays, in the fault detection method of the disclosure.

Step (b) of determining a response characteristic of the time-invariant model may include establishing one or more of the following to describe the transformative effect the one or more portions of transmission medium has on the input operating property at the or each far-end power converter:

(a) an impulse response;

(b) a transfer function;

(c) a differential equation; and

(d) a difference equation.

The foregoing response characteristics are desirably able to fully describe a transformative effect within a linear time-invariant model.

In a preferred embodiment of the disclosure the method includes:

(a) measuring one or both of a first output operating property in the form of a voltage of the transmission medium at the near-end power converter, and a second output operating property in the form of a current of the transmission medium at the near-end power converter; and

(b) deriving one or both of a corresponding first input operating property in the form of a voltage of the transmission medium at the far-end power converter of interest, and a corresponding second input operating property in the form of a current of the transmission medium at the far-end power converter.

Comparison of either a first voltage input operating property or a second current input operating property of the transmission medium at the far-end power converter of interest with a corresponding voltage or current fault threshold can reliably and repeatedly be used to detect a fault on the far-end power converter of interest.

In another preferred embodiment of the disclosure both voltage and current output operating properties are measured and subsequently both corresponding voltage and current input operating properties are derived, and the method additionally includes the step of estimating the power at the far-end power converter of interest from the said derived voltage and current input operating properties.

Such a step provides an indication of the power demanded at a faulty far-end power converter, without the need to introduce communication links, hardware redundancy or additional fail-safe strategies.

A power estimate obtained in the foregoing manner can also be used as a power reference on the healthy side of the faulty far-end power converter to permit a ride through of the fault without collapsing the voltage carried by the transmission medium connected with the said faulty far-end power converter.

In method of detecting a fault on a far-end power converter, within a DC transmission network including a near-end power converter and a plurality of far-end power converters, step (d) of identifying one far-end power converter as a far-end power converter of interest preferably includes testing a respective hypothesis for each far-end power converter that a fault has occurred at the given far-end power converter and the or each other far-end power converter continues to operate normally.

Optionally the step of testing a respective hypothesis for each far-end power converter includes:

(a) ascribing an estimated fault level input operating property of the transmission medium at the given far-end power converter at which the fault is postulated to have occurred;

(b) utilising a known previous input operating property of the transmission medium at the or each other far-end power converter;

(c) applying the response characteristic of the time-invariant model to the estimated fault level input operating property of the transmission medium at the given far-end power converter at which the fault is postulated to have occurred and to the known previous input operating property of the transmission medium at the or each other far-end power converter to obtain an expected theoretical output operating property of the transmission medium at the near-end power converter; and

(d) comparing the expected theoretical output operating property of the transmission medium at the near-end power converter with the measured output operating property of the transmission medium at the near-end power converter.

In a further preferred embodiment of the disclosure the far-end power converter identified as the far-end power converter of interest is the power converter whose respective hypothesis results in the corresponding expected theoretical output operating property most closely matching the measured output operating property of the transmission medium.

The foregoing steps are able, advantageously, to identify the far-end power converter most likely to have a fault on it, with steps (c) and (f) of the disclosure then being able to confirm whether such a fault has actually arisen.

In a method of detecting a fault on a far-end power converter, within a DC transmission network including a near-end power converter, a plurality of far-end power converters and a current flow controller to balance internal currents flowing between the power converters which are mutually interconnected with one another, optionally a current output operating property is measured at the near-end power converter and the response characteristic of the time-invariant model additionally factors in the distribution of internal currents amongst the said power converters.

Preferably the response characteristic additionally factors in the distribution of internal current amongst the said power converters by including a weighting coefficient corresponding to each internal current flow between respective pairs of mutually interconnected power converters.

Such steps beneficially take into account the variation in circulating internal currents purposely carried out by the current flow controller, and hence permits other fault detection steps of the disclosure based on current operating properties to be applied to such DC transmission networks including a current flow controller.

According to a second aspect of the disclosure there is provided a DC transmission network comprising a near-end power converter and at least one far-end power converter interconnected with one another by one or more portions of transmission medium, at least the near-end power converter including a control unit programmed to:

(a) establish a linear time-invariant model of the transmission medium lying between the or each far-end power converter and the near-end power converter;

(b) determine a response characteristic of the time-invariant model;

(c) measure an output operating property of the transmission medium at the near-end power converter;

(d) identify one far-end power converter as a far-end power converter of interest;

(e) derive a corresponding input operating property of the transmission medium at the far-end power converter of interest by applying an inverse of the response characteristic of the time-invariant model to the measured output operating property of the transmission medium at the near-end power converter; and

(f) compare the derived input operating property of the transmission medium at the far-end power converter of interest with a fault characteristic to determine whether there is a fault on the far-end power converter of interest.

The DC transmission network of the disclosure shares the benefits of the corresponding features of the method of the disclosure.

### BRIEF DESCRIPTION OF THE DRAWINGS

There now follows a brief description of preferred embodiments of the disclosure, by way of non-limiting example, with reference being made to the following figures in which:

FIG. 1(A) shows a schematic view of a DC transmission network according to a first embodiment of the disclosure;

FIG. 1(B) shows a linear time-invariant model of a transmission medium forming a part of the DC transmission network shown in FIG. 1(A);

FIG. 2 illustrates the speed of fault detection possible in the DC transmission network shown in FIG. 1(A);

FIG. 3 illustrates the predicted power demanded at a faulty far-end power converter in the DC transmission network shown in FIG. 1(A);

FIG. 4(A) shows a schematic view of a DC transmission network according to a second embodiment of the disclosure;

FIG. 4(B) shows a linear time-invariant model of respective portions of transmission medium forming a part of the DC transmission network shown in FIG. 4(A);

FIG. 4(C) shows a linear time-invariant model of respective portions of transmission medium forming a part of a DC transmission network according to a further embodiment of the disclosure including N−1 far-end power converters; and

FIG. 5 shows a schematic view of a DC transmission network according to a third embodiment of the disclosure.

### DETAILED DESCRIPTION

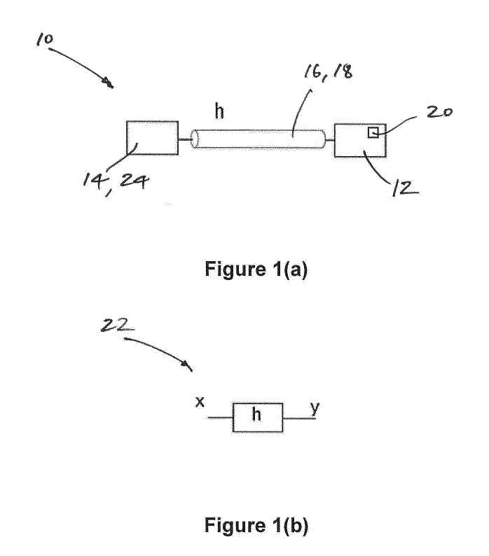

A DC transmission network according to an embodiment of the disclosure is designated generally by reference numeral 10, as shown in FIG. 1(A).

The first DC transmission network 10 includes a near-end power converter 12 and a single far-end power converter 14 which are interconnected with one another by a single, first portion 16 of transmission medium 18, i.e. a single overhead power transmission line or undersea cable. In this manner the first DC transmission network 10 defines a point-to-point DC link. Meanwhile, within the context of the disclosure, a near-end power converter 12 is a power-converter within the local geographical vicinity of which a control unit is arranged to implement a method of detecting a fault on a geographically remote, i.e. distant, far-end power converter 14.

The near-end power converter 12 includes a control unit 20 that is programmed to:

(a) establish a linear time-invariant model of the transmission medium 18 lying between the far-end power converter 14 and the near-end power converter 12;

(b) determine a response characteristic of the time-invariant model;

(c) measure an output operating property of the transmission medium 18 at the near-end power converter 12;

(d) identify the far-end power converter 14 as a far-end power converter of interest;

(e) derive a corresponding input operating property of the transmission medium 18 at the far-end power converter of interest by applying an inverse of the response characteristic of the time-invariant model to the measured output operating property of the transmission medium 18 at the near-end power converter 12; and

(f) compare the derived input operating property of the transmission medium 18 at the far-end power converter of interest with a fault characteristic to determine whether there is a fault on the far-end power converter of interest.

In other embodiments of the disclosure, the far-end power converter 14 may also include a control unit that is similarly programmed such that, with respect to the near-end power converter 12, the far-end power converter 14 is itself able to act as a pseudo near-end power converter in order to detect a fault on the geographically distant near-end power converter 12 (that in turn defines a pseudo far-end power converter).

It follows that the control unit 20 of the near-end power converter 12 is programmed to implement a method of detecting a fault on the far-end power converter 14 according to a first embodiment of the disclosure, i.e. the control unit 20 is programmed to implement a method comprising the steps of:

(a) establishing a linear time-invariant model of the transmission medium 18 lying between the far-end power converter 14 and the near-end power converter 12;

(b) determining a response characteristic of the time-invariant model;

(c) measuring an output operating property of the transmission medium 18 at the near-end power converter 12;

(d) identifying the far-end power converter 14 as a far-end power converter of interest;

(e) deriving a corresponding input operating property of the transmission medium 18 at the far-end power converter of interest by applying an inverse of the response characteristic of the time-invariant model to the measured output operating property of the transmission medium 18 at the near-end power converter 12; and

(f) comparing the derived input operating property of the transmission medium 18 at the far-end power converter of interest with a fault characteristic to determine whether there is a fault on the far-end power converter of interest.

More particularly, step (a) of establishing a time-invariant model of the transmission medium 18 lying between the far-end power converter 14 and the near-end power converter 12, i.e. establishing a model whose response can be used to infer an input operating property x of the transmission medium 18 at the far-end power converter 14 that gave rise to an available measured output operating property y of the transmission medium 18 at the near-end power converter 12, includes establishing a model 22 as shown in FIG. 1(B) in which h is a response characteristic of the model 22.

In the embodiment described, step (b) of the method includes determining the response characteristic h of the time-invariant model 22 as an impulse response of the transmission medium 18, although in other embodiments of the disclosure the response characteristic may instead be a transfer function, differential equation or difference equation which similarly denotes the transformative effect the transmission medium 18 has on an input operating property x at the far-end power converter 14.

In any event the impulse response h or other response characteristic of the time-invariant model 22 can be obtained from experimental results or theoretical analysis of the transmission medium 18, i.e. the single portion 16 of overhead transmission line or undersea transmission cable lying between the near-end power converter 12 and the far-end power converter 14.

In connection with the first method of the disclosure a step change in voltage is applied to the transmission medium 18 at the far-end power converter 14, i.e. at an input to the time-invariant model 22, and the measured step response is differentiated to give the following voltage impulse response characteristic hᵥ(n)

$${h}_{v} ( n ) = \{ \begin{matrix}A sin ( 2 π {f}_{0} {T}_{s} n ) {e}^{- α {T}_{s} n} , & n \geq 0 \\ 0 , & n < 0\end{matrix}$$

where,

(a) the coefficients A, f₀, α are established by employing a curve fitting technique, and Tₛ is the sampling time.

Other response characteristics may, however, be determined.

For example, in other embodiments of the disclosure, a continuous time voltage impulse in the form of a Dirac impulse may instead be applied to the transmission medium at the far-end power converter within a theoretical representation of the first DC transmission network 10, e.g. a computer simulation, to similarly establish an impulse response characteristic.

Thereafter step (c) of the method includes measuring both a first output operating property yₐ in the form of a voltage of the transmission medium 18 at the near-end power converter 12, and a second output operating property y_{b} in the form of a current of the transmission medium 18 at the near-end power converter 12.

The first method of the disclosure then identifies the single far-end power converter 14 as the far-end power converter of interest 24.

Step (e) of the first method of the disclosure then includes deriving both a corresponding first input operating property xₐ in the form of a voltage of the transmission medium 18 at the far-end power converter 14, and a corresponding second input operating property x_{b} in the form of a current of the transmission medium 18 at the far-end power converter 14.

More particularly, in considering the inputs xₐ,x_{b} and outputs yₐ,y_{b} of the time-invariant model 22 shown in FIG. 1(B), an output function y(t) is obtained by using a convolution product, i.e. a mathematical operation in which the output function y(t) is a modified version of an input function x(t), defined as

$$\begin{matrix}y ( t ) = h ( t ) * x ( t ) \\ = {\int }_{- ∞}^{+ ∞} h ( t - τ ) x ( τ ) d τ \\ = {\int }_{- ∞}^{+ ∞} h ( τ ) x ( t - τ ) d τ\end{matrix}$$

The control unit 20 of the near-end power converter 12 is programmed to operate in conjunction with digital signal processors which sample input data before processing them. Consequently the continuous analogue measured output operating properties yₐ, y_{b} of the transmission medium 18 at the near-end power converter 12 are provided in a discrete form and so the above convolution product is similarly reconstituted in a discrete form, i.e.

$$\begin{matrix}( n ) = {\sum }_{k = - ∞}^{+ ∞} h ( n - k ) x ( k ) \\ = {\sum }_{k = - ∞}^{+ ∞} h ( k ) x ( n - k )\end{matrix}$$

$$where , \\ i . y ( n ) {=}^{Δ} y ( {nT}_{s} )$$

with

(b) n being a respective sample; and

(c) Tₛ being the sample time.

Moreover, since the first DC transmission network 10 is a real system the time-invariant model 22 can only be causal, i.e. its output y(n) can only depend on present and past inputs x(n) and not future inputs. Hence, with respect to the response characteristic h(n),

h(n)=0 for n<0

and so the above discrete convolution product becomes

$$y ( n ) = {\sum }_{k = 0}^{+ ∞} h ( k ) x ( n - k )$$

As indicated above, a voltage impulse response hᵥ(n), one of many such possible response characteristics that may be used, is established for the first time-invariant model 22 of the form

$${h}_{v} ( n ) = \{ \begin{matrix}A sin ( 2 π {f}_{0} {T}_{s} n ) {e}^{- α {T}_{s} n} , & n \geq 0 \\ 0 , & n < 0\end{matrix}$$

In addition to the foregoing, the control unit 20 converts the voltage impulse response hᵥ(n) into a voltage transfer function Hᵥ(z) in the Z-domain using a Z-transformation to relate a transformed input operating property X(z) and a transformed output operating property Y(z) according to

$${H}_{v} ( z ) = \frac{Y ( z )}{X ( z )}$$

which gives

$${H}_{v} ( z ) = A \frac{{e}^{- α {T}_{s}} sin ( 2 π {f}_{0} {T}_{s} ) {z}^{- 1}}{1 - 2 {e}^{- α {T}_{s}} cos ( 2 π {f}_{0} {T}_{s} ) {z}^{- 1} + {e}^{- 2 α {T}_{s}} {z}^{- 2}}$$

It follows that the input operating property X(z) can be derived from a measured output operating property Y(z) by applying an inverse Hᵥ⁻¹(z) of the response characteristic, i.e. the inverse of the voltage transfer function H (z), according to

X(z)=Hᵥ⁻¹(z)Y(z)

where,

Hᵥ⁻¹(z)=1/Hᵥ(z)

Accordingly, the control unit 20 is able to derive an estimate of the first input operating voltage xₐ of the transmission medium 18 at the far-end power converter 14 by applying the inverse response characteristic Hᵥ⁻¹(z) to the measured first output operating voltage yₐ of the transmission medium 18 at the near-end converter 12.

More particularly, the control unit 20 is programmed to generate, using the inverse response characteristic Hᵥ⁻¹(z), a difference equation in the time domain of the following form

$${x}_{a} ( n ) = \frac{1}{A sin ( 2 π {f}_{0} {T}_{s} )} [ {e}^{α {T}_{s}} {y}_{a} ( n + 1 ) - 2 cos ( 2 π {f}_{0} {T}_{s} ) {y}_{a} ( n ) + {e}^{- α {T}_{s}} {y}_{a} ( n - 1 ) ]$$

Since the foregoing equation represents a non-causal system, it can be delayed by one sample n to represent a causal system

x_{a′}(n) [symbol] x(n−1)

i.e.

$${x}_{{a}^{′}} ( n ) = \frac{1}{A sin ( 2 π {f}_{0} {T}_{s} )} [ {e}^{α {T}_{s}} {y}_{a} ( n ) - 2 cos ( 2 π {f}_{0} {T}_{s} ) {y}_{a} ( n - 1 ) + {e}^{- α {T}_{s}} {y}_{a} ( n - 2 ) ]$$

Hence, from respective measured output operating voltage samples yₐ(n), yₐ(n−1) and yₐ(n−2) the input operating voltage x_{a′} of the transmission cable 18 at the far-end power converter 14 can be derived.

In addition to the foregoing, the control unit 20 is programmed to implement step (f) of the first method of the disclosure to compare the derived input operating voltage x_{a′} of the transmission medium 18 at the far-end power converter of interest 24 with a fault characteristic to determine whether there is a fault 26 on the far-end power converter of interest 24.

In the embodiment of the method of the disclosure described herein, the fault characteristic takes the form of a fault threshold, and more particularly a static fault voltage threshold.

In other embodiments of the disclosure, however, the fault threshold may not be static, i.e. may vary over time, and indeed other fault characteristics such a wave shape or voltage ranges may be used.

Step (f) of the first method of the disclosure includes predicting whether the derived input operating voltage xₐ, will meet the fault voltage threshold, with such a prediction being realised by considering the rate of change of the derived input operating voltage x_{a′}.

More particularly the control unit 20 is programmed to predict the input operating voltage x_{a′} a number of steps M ahead (which preferably is at least one step ahead) by fitting respective derived input operating voltage x_{a′} values to a curve using an m-point least-squares estimation technique. Other estimation techniques may, however, also be used.

Such curve fitting is achieved by denoting a curve-fitted vector as \tilde{x}′ (n), with

\tilde{x}′(n)=a n+b

and a and b being given by a least-squares estimator which, by way of example, takes the form

$$[ \begin{matrix}a \\ b\end{matrix} ] = [ B ( k ) {B}^{- 1} ( k ) ] \cdot {B}^{T} ( k ) \cdot {x}^{′} ( k )$$

in which,

$$B = [ \begin{matrix}k & 1 \\ ( k - 1 ) & 1 \\ ⋮ & \\ ( k - m + 1 ) & 1\end{matrix} ] ;$$

and
the observations vector x′(k) is given by

$${x}^{′} ( k ) = [ \begin{matrix}{x}^{′} ( k ) \\ {x}^{′} ( k - 1 ) \\ ⋮ \\ {x}^{′} ( k - m + 1 )\end{matrix} ]$$

Accordingly, a predicted input operating voltage M steps ahead is given by

x̆′(n+M)=a(n+M)+b

The control unit 20 indicates that there is a fault on the far-end power converter 14 when the predicted input operating voltage x̆′(n+M) M steps ahead meets the fault voltage threshold.

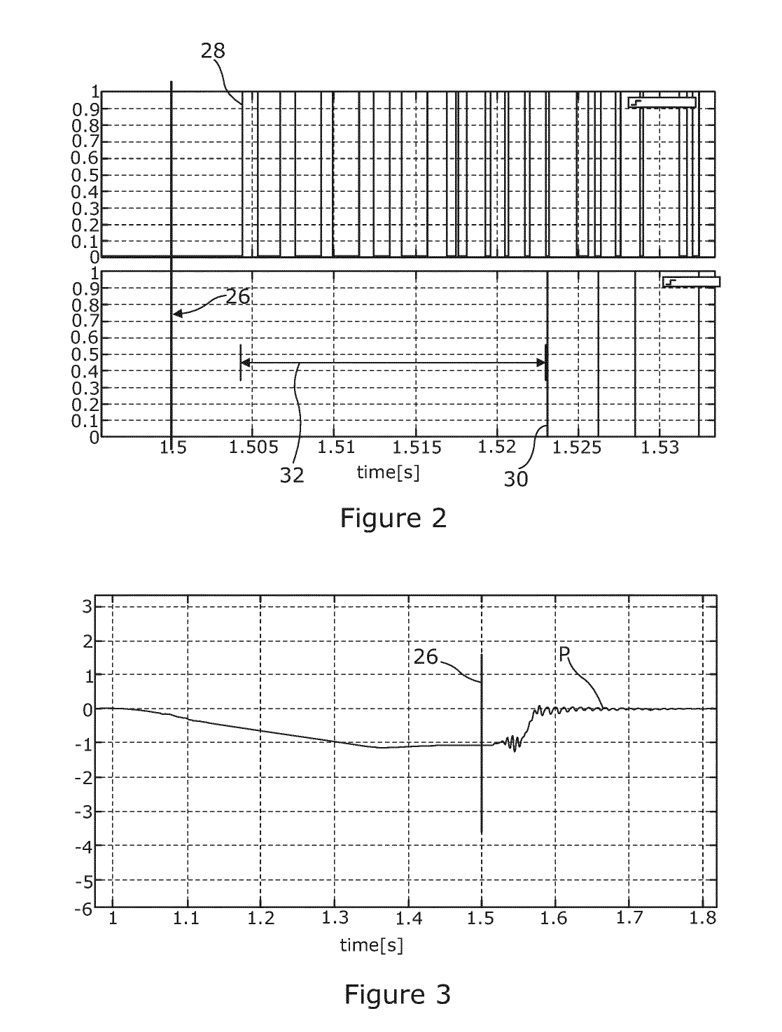

The effectiveness of the first method of the disclosure is illustrated in FIG. 2 which shows that for a single phase fault 26 occurring at the far-end power converter 14 at 1.5 seconds, the predictive approach 28 of the first method of the disclosure detects the fault 26 at 1.504 seconds, i.e. only 4 milliseconds after the fault 26 occurs, whereas a conventional 90% voltage threshold technique 30 takes a further period 32 of approximately 19 milliseconds to detect the fault 26.

The control unit 20 is similarly programmed to derive an estimate of the second input operating current x_{b} of the transmission medium 18 at the far-end power converter 14 by applying the inverse response characteristic Hᵥ⁻¹(z) to the measured second output operating current y_{b} of the transmission medium 18 at the near-end converter 12.

From such derived estimates of the first and second input operating voltage xₐ and current x_{b} the control unit 20 estimates the power P in the transmission medium 18 at the far-end power converter of interest 24 by multiplying the said estimated first and second input operating voltage xₐ and current x_{b}.

This allows, as shown in FIG. 3, the estimated power P to be used as a power reference on the healthy side of the far-end power converter 14 to allow the fault 26 to be ridden through without collapsing the voltage of the transmission medium 18.

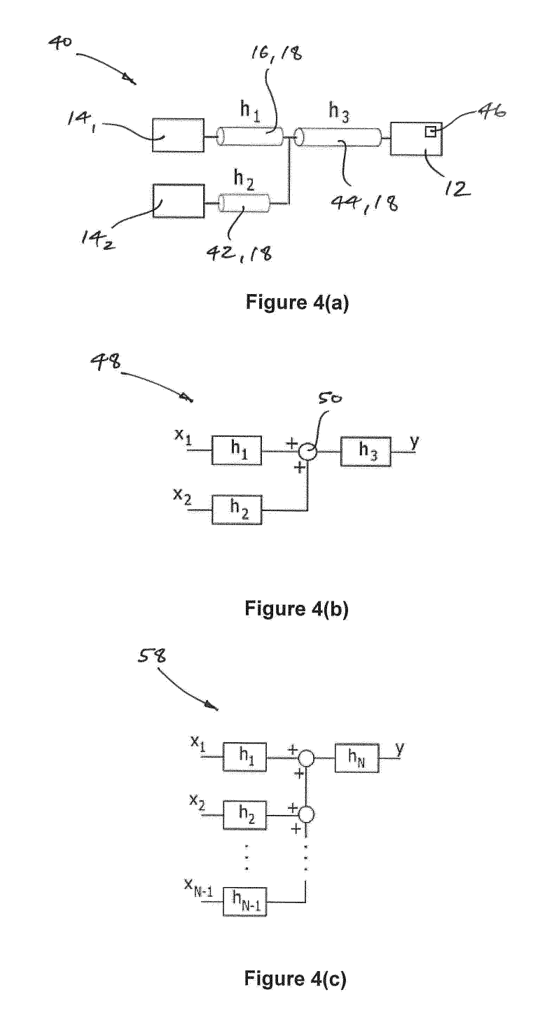

A DC transmission network 40 according to a further embodiment of the disclosure is shown schematically in FIG. 4(A).

The second DC transmission network 40 includes a near-end power converter 12 and two far-end power converters 14 and in this manner defines a multi-terminal DC link. The power converters 12, 14 are shown interconnected with one another by first, second and third portions 16, 42, 44 of transmission medium 18 in a star topology. The arrangement of the power converters 12, 14 and interconnecting transmission medium 18 in the second DC transmission network 40 may actually define a different topology, such as a delta topology.

The star topology shown in FIG. 4(A) is just one way in which the transmission medium 18 arrangement in the actual second DC transmission network 40 may be represented, and other topologies may instead be used to represent the transmission medium 18 arrangement.

In a similar manner to the first DC transmission network 10, the near-end power converter 12 in the second DC transmission network 40 includes a control unit 46. The second control unit 46 is, however, programmed differently to the first control unit 20.

More particularly the second control unit 46 is programmed to:

(a) establish a linear time-invariant model of the transmission medium 18 lying between the two far-end power converters 14 and the near-end power converter 12;

(b) determine a response characteristic of the time-invariant model;

(c) measure an output operating property of the transmission medium 18 at the near-end power converter 12;

(d) identify one far-end power converter 14 as a far-end power converter of interest;

(e) derive a corresponding input operating property of the transmission medium 18 at the far-end power converter of interest by applying an inverse of the response characteristic of the time-invariant model to the measured output operating property of the transmission medium 18 at the near-end power converter 12; and

(f) compare the derived input operating property of the transmission medium 18 at the far-end power converter of interest with a fault characteristic to determine whether there is a fault on the far-end power converter of interest.

In other embodiments of the disclosure, one or both of the far-end power converters 14 may also include a second control unit so that each is itself able to act as a pseudo near-end power converter in order to detect a fault on one of the other power converters.

The second control unit 46 of the near-end power converter 12 in the second DC transmission network 40 is accordingly programmed to implement a method of detecting a fault on a far-end power converter of interest according to a second embodiment of the disclosure.

The second control unit 46 is so programmed to implement a second method comprising the steps of:

(a) establishing a linear time-invariant model of the transmission medium 18 lying between the far-end power converters 14 and the near-end power converter 12;

(b) determining a response characteristic of the time-invariant model;

(c) measuring an output operating property of the transmission medium 18 at the near-end power converter 12;

(d) identifying one far-end power converter 14 as a far-end power converter of interest;

(e) deriving a corresponding input operating property of the transmission medium 18 at the far-end power converter of interest by applying an inverse of the response characteristic of the time-invariant model to the measured output operating property of the transmission medium 18 at the near-end power converter 12; and

(f) comparing the derived input operating property of the transmission medium 18 at the far-end power converter of interest with a fault characteristic to determine whether there is a fault on the far-end power converter of interest.

Step (a) of establishing a time-invariant model of the transmission medium 18 lying between the far-end power converters 14 and the near-end power converter 12 includes establishing a model 48 as shown in FIG. 4(B).

The overall response characteristic of such a time-invariant model 48 is given by

y(n)=h₃(n)*[x₁(n)*h₁(n)+x₂(n)*h₂(n)]

where,

(a) h₁ is an individual response characteristic of the first portion 16 of transmission medium lying between one far-end power converter 14 and a star junction 50;

(b) h₂ is an individual response characteristic of the second portion 42 of transmission medium lying between the other far-end power converter 14 and the star junction 50; and

(c) h₃ is an individual response characteristic of the third portion 44 of transmission medium lying between the near-end power converter 14 and the star junction 50, with each of the individual response characteristics h₁, h₂, h₃ taking the form of a voltage impulse response, i.e.

$${h}_{v} ( n ) = \{ \begin{matrix}A sin ( 2 π {f}_{0} {T}_{s} n ) {e}^{- α {T}_{s} n} , & n \geq 0 \\ 0 , & n < 0\end{matrix}$$

where,

(d) the coefficients A, f₀, α are established by employing a curve fitting technique, and Tₛ is the sampling time.

Other response characteristics may be used however.

Meanwhile step (c) of the second method includes measuring the output operating voltage y of the transmission medium 18 at the near-end power converter 12.

In the meantime, step (d) of identifying one of the far-end power converter 14 as the far-end power converter of interest 24 includes testing a respective hypothesis for each far-end power converter 14 that a fault has occurred at the given far-end power converter 14 while the other far-end power converter 14 continues to operate normally.

More particularly, testing a respective hypothesis for each far-end power converter 14 includes:

(a) ascribing an estimated fault level input operating voltage x_{STEP} of the transmission medium 18 at the given far-end power converter 14 at which the fault is postulated to have occurred;

(b) utilising a known previous input operating voltage x₁_{_{OP}}, x₂_{_{OP}}, of the transmission medium at the other far-end power converter 14; and

(c) applying the overall response characteristic of the time-invariant model 48 to the estimated fault level input operating voltage x_{STEP} of the transmission medium 18 at the given far-end power converter 14 at which the fault is postulated to have occurred and to the known previous input operating voltage x₁_{_{OP}}, x₂_{_{OP}}, of the transmission medium 18 at the or each other far-end power converter 14 to obtain an expected theoretical output operating voltage ŷ⁽¹⁾(n), ŷ⁽²⁾(n) of the transmission medium 18 at the near-end power converter 12.

In other words:

according to a first hypothesis the fault occurred at a first far-end power converter 14₁, and so the estimated fault level input operating voltage x_{STEP} is considered to be the input operating voltage \hat{x}₁⁽¹⁾(n) of the transmission medium 18 at the said first far-end power converter 14₁, i.e.

\hat{x}₁⁽¹⁾(n)=x_{STEP}

while the known previous input operating voltage x₂_{_{OP}} of the other, i.e. a second far-end power converter 14₂, is utilised as the input operating voltage \hat{x}₂⁽¹⁾(n) of the other, second far-end power converter 14₂, i.e.

\hat{x}₂⁽¹⁾(n)=x₂_{_{OP}}

such that when the overall response characteristic of the time-invariant model 48 is applied the expected theoretical output operating voltage ŷ⁽¹⁾(n) is given by

ŷ⁽¹⁾(n)=h₃(n)*[\hat{x}₁⁽¹⁾(n)*h₁(n)+\hat{x}₂⁽¹⁾(n)*h₂(n)]; and

according to a second hypothesis the fault occurred at the second far-end power converter 14₂, and so the estimated fault level input operating voltage x_{STEP} is considered to be the input operating voltage \hat{x}₂⁽²⁾(n) of the transmission medium 18 at the said second far-end power converter 14₂, i.e.

\hat{x}₂⁽²⁾(n)=x_{STEP}

while the known previous input operating voltage x₁_{_{OP}} of the other, i.e. the first far-end power converter 14₁, is utilised as the input operating voltage \hat{x}₁⁽²⁾(n) of the other, first far-end power converter 14₁, i.e.

\hat{x}₁⁽²⁾(n)=x₁_{_{OP}}

such that when the overall response characteristic of the time-invariant model 48 is applied the expected theoretical output operating voltage ŷ⁽²⁾(n) is given by

ŷ⁽²⁾(n)=h₃(n)*[\hat{x}₁⁽²⁾(n)*h₁(n)+\hat{x}₂⁽²⁾(n)*h₂(n)]

Thereafter, testing a respective hypothesis for each far-end power converter 14 includes comparing the expected theoretical output operating voltage ŷ⁽¹⁾(n), ŷ⁽²⁾(n) of the transmission medium 18 at the near-end power converter 12 established under the associated hypothesis with the actual measured output operating voltage y of the transmission medium 18 at the near-end power converter 12.

More particularly, the far-end power converter 14₁, 14₂ identified as the far-end power converter of interest is the power converter 14₁, 14₂ whose respective hypothesis results in the corresponding expected theoretical output operating voltage ŷ⁽¹⁾(n), ŷ⁽²⁾(n) most closely matching the measured output operating voltage y of the transmission medium 18 at the near-end power converter 12.

One way in which the most closely matching hypothesis may be identified is to select the first hypothesis, i.e. consider the fault to be at the first far-end power converter 14₁ (such that the first far-end power converter 14₁ is identified as the far-end power converter of interest) if

$${\sum }_{n = 0}^{L - 1} \vert {\hat{y}}^{( 1 )} ( n ) - y ( n ) \vert < {\sum }_{n = 0}^{L - 1} \vert {\hat{y}}^{( 2 )} ( n ) - y ( n ) \vert$$

or otherwise select the second hypothesis (and thereby identify the second far-end power converter 14₂ as the far-end power converter of interest).

In the comparative equation shown above L is the length of the data vector chosen based on a tolerable delay introduced by the decision logic, i.e. is the number of consecutive iterations of the comparison carried out before a final decision is taken.

In other embodiments of the disclosure respective expected theoretical output operating currents may instead be calculated and compared with measured output operating currents in order to identify a single far-end power converter 14₁, 14₂ as the far-end power converter of interest.

In any event, once a far-end converter of interest has been identified, step (e) of the second method of the disclosure is carried out to derive the actual estimated input operating voltage \hat{x}₁ (n), \hat{x}₂ (n) of the transmission medium 18 at the said far-end power converter of interest to replace the previously utilised estimated fault level input operating voltage x_{STEP}.

The overall response characteristic of the time-invariant model 48, i.e.

y(n)=h₃(n)*[x₁(n)*h₁(n)+x₂(n)*h₂(n)]

is, in a similar manner to the first method of the disclosure, again used for this step with the input operating voltage \hat{x}₁ (n), \hat{x}₂ (n) of the transmission medium 18 at the other far-end power converter being taken as the corresponding known previous input operating voltage x₁_{_{OP}}, x₂_{_{OP}}, such that rearrangement of the above-equation, i.e. applying an inverse of the overall response characteristic, allows the actual corresponding estimated input operating voltage \hat{x}₁ (n), \hat{x}₂ (n) of the transmission medium 18 at the said far-end power converter of interest to be derived.

Such actual corresponding estimated input operating voltage \hat{x}₁ (n), \hat{x}₂ (n) of the transmission medium 18 at the said far-end power converter of interest is then compared with a fault voltage threshold in a similar manner, i.e. a predictive manner, to that set out in connection with the first method of the disclosure. The actual corresponding estimated input operating voltage \hat{x}₁ (n), \hat{x}₂ (n) of the transmission medium 18 at the said far-end power converter of interest may, in other embodiments of the disclosure, be compared with some other fault characteristic in order to determine whether there is a fault on the far-end power converter of interest.

In addition, in a similar manner an estimated input operating current may instead be derived and compared with a fault current threshold, and if both estimated input voltage and current values are derived then the power at the far-end power converter of interest may also be estimated.

Furthermore, the second method of the disclosure may be generalised to cover multi-terminal DC transmission networks which have N−1 power converters 12, 14.

In such a generalised second method of the disclosure, establishing a linear time-invariant model includes establishing a third time-invariant model 58, as shown in FIG. 4(C).

Meanwhile, determining an overall response characteristic of the third time-invariant model 58 gives rise to

$$y ( n ) = {h}_{N} ( n ) * {\sum }_{i = 1}^{N - 1} {x}_{i} ( n ) * {h}_{i} ( n )$$

where the individual response characteristic h₁ . . . h_{N} of each respective portion of transmission medium is known.

Thereafter, generalising a hypothesis for each far-end power converter 14 that it might be at fault leads to:

Hypothesis 1: the fault occurred at a first far-end power converter 14₁. Then

\hat{x}₁⁽¹⁾(n)=x_{STEP}

\hat{x}ⱼ^{(N-1)}(n)=xⱼ_{_{OP}}, j=2,3 . . . ,N−1

with each previous input operating property being known.
Hypothesis 2: the fault occurred at a second far-end power converter 14₂. Then
(a) .
(b) .
(c) .
   Hypothesis N−1: the fault occurred at far-end power converter 14N−1. Then

\hat{x}_{N-1}^{(N-1)}(n)=x_{STEP}

\hat{x}ⱼ^{(N-1)}(n)=xⱼ_{_{OP}}, j=1,2 . . . ,N−2

In general, all the hypotheses can be expressed into the following closed form:

For each k=1, 2, . . . , N−1, state the following:
Hypothesis k: the fault occurred at far-end power converter 14k. Then

\hat{x}ₖ^{(k)}(n)=x_{STEP}

\hat{x}ⱼ^{(k)}(n)=xⱼ_{_{OP}}, j=1,2 . . . ,N−1, j≠k

Combining this with the overall response characteristic of the third time-invariant model 58, to allow respective expected theoretical output operating properties ŷ^{(q)}(n) to be obtained, gives

$${\hat{y}}^{( k )} ( n ) = {h}_{N} ( n ) * {\sum }_{\begin{matrix}i = 1 \\ i \neq k\end{matrix}}^{N - 1} {\hat{x}}_{i}^{( k )} ( n ) * {h}_{i} ( n )$$

such that the hypothesis q which gives rise to the closes match between the theoretical output operating property ŷ^{(q)}(n) and the actual measured output operating property y(n) can be determined by

$${\sum }_{i = 1}^{L} \vert {\hat{y}}^{( q )} ( n ) - y ( n ) \vert = {min}_{k} {\sum }_{i = 1}^{L} \vert {\hat{y}}^{( k )} ( n ) - y ( n ) \vert , q , k = 1 , 2 , … , N - 1$$

Where q is the particular value of k that minimises |ŷ^{(k)}(n)−y(n)| over L consecutive samples and for all possible values of k.

In addition, the estimated fault level input operating voltage \hat{x}_{q}, i.e. x_{STEP}, can be further refined by deriving its expression from the measured output operating properties y(n) and employing

$$y ( n ) = {h}_{N} * {\sum }_{i = 1}^{N - 1} {x}_{i} ( n ) * {h}_{i} ( n )$$

for the case \hat{x}ⱼ^{(k)}=xⱼ_{_{OP}}, with j=1, 2, . . . , N−1, and j≠q.

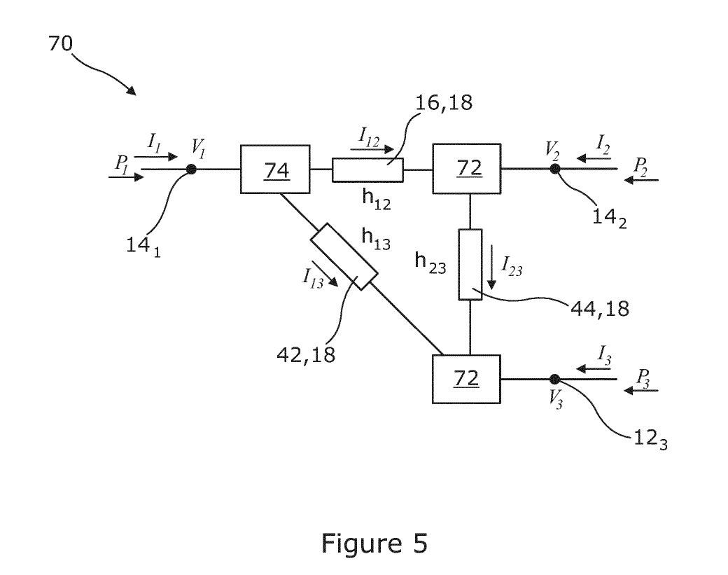

A DC transmission network 70 according to a further embodiment of the disclosure is shown schematically in FIG. 5.

The third DC transmission network 70 is similar to the DC transmission network 40 shown in FIG. 4(a) and like features share the same reference numerals. To that end the third DC transmission network 70 includes a near-end power converter 12₃ and two far-end power converters 14₁, 14₂ and in this manner similarly defines a multi-terminal DC link.

The power converters 12₃, 14₁, 14₂ are mutually interconnected with one another by first, second and third portions 16, 42, 44 of transmission medium 18 that are mechanically and electrically connected to one another at respective connection points 72.

The third DC transmission network 70 also includes a current flow controller 74 which balances internal currents I₁₂, I₁₃, I₂₃ that flow between the said power converters 12₃, 14₁, 14₂. More particularly, the current flow controller 74 appreciably alters the internal currents I₁₂, I₁₃, I₂₃ by modifying the voltage across each portion 16, 42, 44 of transmission medium 18.

Each said portion 16, 42, 44 of transmission medium 18 has a corresponding individual response characteristic h₁₂, h₁₃, h₂₃, which preferably is (as is the case in association with the first and second methods of the disclosure) an individual voltage impulse response of the form

$${h}_{v} ( n ) = \{ \begin{matrix}A sin ( 2 π {f}_{0} {T}_{s} n ) {e}^{- α {T}_{s} n} , & n \geq 0 \\ 0 , & n < 0\end{matrix}$$

The current flow controller 74 does not produce a noticeable change in the voltage of the various transmission medium portions 16, 42, 44. Therefore, with respect to the measurement of an output operating voltage of the transmission medium 18 at the near-end power converter 12₃ and the subsequent derivation of a corresponding input operating voltage of the transmission medium 18 at a given far-end power converter 14₁, 14₂ of interest, the second method of the disclosure described hereinabove can be applied to the third DC transmission network 70 in order to detect a fault at one or other of the far-end power converters 14₁, 14₂, i.e. by making use of a first overall response characteristic (which in turn is determined in part using the Superposition Principle) of the form

y₃(n)=h₁₃(n)*x₁(n)+h₂₃(n)*x₂(n)

In contrast, when wishing to measure an output operating current of the transmission medium 18 at the near-end power converter 12₃ and subsequently derive a corresponding input operating current of the transmission medium 18 at a given far-end power converter 14₁, 14₂ of interest, it is necessary to factor in the distribution of circulating internal currents I₁₂,I₁₃ (and consequently I₂₃) since the current flow controller 74 varies these while leaving the terminal current I₁, I₂, I₃ at each power converter 12₃, 14₁, 14₂ unchanged.

Consequently, a method according to a third embodiment of the disclosure of detecting a fault in the third DC transmission network 70 is similar to the second method of the disclosure but additionally factors in the distribution of internal currents I₁₂, I₁₃, I₂₃ amongst the said power converters 12₃, 14₁, 14₂ by including a weighting coefficient corresponding to each internal current flow I₁₂, I₁₃, I₂₃ between respective pairs of mutually interconnected power converters 12₃, 14₁, 14₂.

More particularly, in the third method of the disclosure a first weighting coefficient a₁₂ is applied to the first transmission medium portion 16 having a first individual response characteristic h₁₂, a second weighting coefficient a₁₃ is applied to the second transmission medium portion 42 having a second individual response characteristic h₁₃, and a third weighting coefficient a₂₃ is applied to the third transmission medium portion 44 having a third individual response characteristic h₂₃.

The respective weighting coefficients a₁₂, a₁₃, a₂₃ sum to 1 and each is known by all of the power converters 12₃, 14₁, 14₂.

Consequently, with respect to the near-end power converter 12₃, the measured output operating current I₃ is given by the sum of the terminal currents I₁,I₂ at the two far-end power converters 14₁, 14₂ such that a second, current-based, overall response characteristic is given by

y₃(n)=\tilde{h}₁₃(n)*x₁(n)+\tilde{h}₂₃(n)*x₂(n)

where,
(a) y₃=I₃;
(b) x₁=I₁; and
i. x₂=I₂
and
(c) \tilde{h}₁₃ is given by

ƒ₁(h₁₂,h₁₃,h₂₃,a₁₂,a₁₃,a₂₃)┘ₓ_{₂}₌₀; and

(d) \tilde{h}₂₃ is given by

ƒ₂(h₁₂,h₁₃,h₂₃,a₁₂,a₁₃,a₂₃)┘ₓ_{₁}₌₀

i.e. the expressions \tilde{h}₁₃ and \tilde{h}₂₃ are themselves given by respective time-invariant functions ƒ₁ and ƒ₂ such that subsequent steps essentially identical to those in the second method of the disclosure can then be utilised in the third method of the disclosure to detect a fault at one or other of the far-end power converters 14₁, 14₂ in the third DC transmission network 70 by making use of measured and derived current operating properties and the second overall response characteristic, i.e.

y₃(n)=\tilde{h}₁₃(n)*x₁(n)+\tilde{h}₂₃(n)*x₂(n)

as set out hereinabove.

What we claim is:

1. A method of detecting a fault on a far-end power converter within a DC transmission network comprising a near-end power converter and at least one far-end power converter interconnected with one another by one or more portions of transmission medium, the method comprising the steps of:
(a) establishing a linear time-invariant model of the transmission medium lying between the or each far-end power converter and the near-end power converter;
(b) determining a response wherein of the time-invariant model;
(c) measuring an output operating property of the transmission medium at the near-end power converter;
(d) identifying one far-end power converter as a far-end power converter of interest;
(e) deriving a corresponding input operating property of the transmission medium at the far-end power converter of interest by applying an inverse of the response further comprising of the time-invariant model to the measured output operating property of the transmission medium at the near-end power converter; and
(f) comparing the derived input operating property of the transmission medium at the far-end power converter of interest with a fault characteristic to determine whether there is a fault on the far-end power converter of interest.

2. A method according to claim 1, wherein step (f) of comparing the derived input operating property of the transmission medium at the far-end power converter of interest with a fault characteristic to determine whether there is a fault on the far-end power converter of interest includes predicting whether the derived input operating property will meet the fault characteristic and indicating that there is a fault on the far-end power converter of interest when the derived input operating property is predicted to meet the fault characteristic.

3. A method according to claim 2, wherein predicting whether the derived input operating property will meet the fault characteristic includes determining an expected output operating property at least one step ahead.

4. A method according to claim 1, wherein step (b) of determining a response wherein of the time-invariant model includes establishing one or more of the following to describe the transformative effect the one or more portions of transmission medium has on the input operating property at the or each far-end power converter:
an impulse response;
a transfer function;
a differential equation; and
a difference equation.

5. A method according to claim 1, including: measuring one or both of a first output operating property in the form of a voltage of the transmission medium at the near-end power converter, and a second output operating property in the form of a current of the transmission medium at the near-end power converter; and
deriving one or both of a corresponding first input operating property in the form of a voltage of the transmission medium at the far-end power converter of interest, and a corresponding second input operating property in the form of a current of the transmission medium at the far-end power converter.

6. A method according to claim 5, wherein both voltage and current output operating properties are measured and subsequently both corresponding voltage and current input operating properties are derived, additionally includes the step of estimating the power at the far-end power converter of interest from the said derived voltage and current input operating properties.

7. A method according to claim 1, of detecting a fault on a far-end power converter, within a DC transmission network including a near-end power converter and a plurality of far-end power converters, wherein step (d) of identifying one far-end power converter as a far-end power converter of interest includes testing a respective hypothesis for each far-end power converter that a fault has occurred at the given far-end power converter and the or each other far-end power converter continues to operate normally.

8. A method according to claim 7, wherein the step of testing a respective hypothesis for each far-end power converter includes:
ascribing an estimated fault level input operating property of the transmission medium at the given far-end power converter at which the fault is postulated to have occurred;
utilising a known previous input operating property of the transmission medium at the or each other far-end power converter;
applying the response wherein of the time-invariant model to the estimated fault level input operating property of the transmission medium at the given far-end power converter; at which the fault is postulated to have occurred and to the known previous input operating property of the transmission medium at the or each other far-end power converter; to obtain an expected theoretical output operating property of the transmission medium at the near-end power converter; and
comparing the expected theoretical output operating property of the transmission medium at the near-end power converter with the measured output operating property of the transmission medium at the near-end power converter.

9. A method according to claim 8, wherein the far-end power converter identified as the far-end power converter of interest is the power converter whose respective hypothesis results in the corresponding expected theoretical output operating property most closely matching the measured output operating property of the transmission medium.

10. A method according to claim 1, including a near-end power converter, a plurality of far-end power converters and a current flow controller to balance internal currents flowing between the power converters which are mutually interconnected with one another, wherein a current output operating property is measured at the near-end power converter and the response wherein of the time-invariant model additionally factors in the distribution of internal currents amongst the said power converters.

11. A method according to claim 10, wherein the response characteristic additionally factors in the distribution of internal currents amongst the said power converters by including a weighting coefficient corresponding to each internal current flow between respective pairs of mutually interconnected power converters.

12. A DC transmission network comprising a near-end power converter and at least one far-end power converter interconnected with one another by one or more portions of transmission medium, at least the near-end power converter including a control unit programmed to:
(a) establish a linear time-invariant model of the transmission medium lying between the or each far-end power converter and the near-end power converter;
(b) determine a response characteristic of the time-invariant model;
(c) measure an output operating property of the transmission medium at the near-end power converter;
(d) identify one far-end power converter as a far-end power converter of interest;
(e) derive a corresponding input operating property of the transmission medium at the far-end power converter of interest by applying an inverse of the response wherein of the time-invariant model to the measured output operating property of the transmission medium at the near-end power converter; and
(f) compare the derived input operating property of the transmission medium at the far-end power converter of interest with a fault characteristic to determine whether there is a fault on the far-end power converter of interest.
